(19) United States
(12) Patent Application Publication
(10) Pub. No.: US 2014/0191275 A1
(43) Pub. Date: Jul. 10, 2014

(54) CERAMIC SUBSTRATE ADAPTED TO MOUNTING ELECTRONIC COMPONENT AND ELECTRONIC COMPONENT MODULE

(71) Applicant: PANASONIC CORPORATION, Osaka (JP)

(72) Inventor: Takashi AIBARA, Kyoto (JP)

(73) Assignee: PANASONIC CORPORATION, Osaka (JP)

(21) Appl. No.: 14/146,652

(22) Filed: Jan. 2, 2014

Related U.S. Application Data
(60) Provisional application No. 61/750,541, filed on Jan. 9, 2013.

(51) Int. Cl. H05K 1/03; H05K 1/18; H01L 33/60; H05K 1/09

(52) U.S. Cl. CPC H05K 1/0306; H05K 1/09; H05K 1/181; H01L 33/60
USPC 257/99; 174/258; 174/257

(57) ABSTRACT

To provide a ceramic substrate having a reflective film formed on the surface thereof that is suitable for mounting electronic components such as LEDs, a ceramic substrate 1 includes a ceramic substrate body 2, a terminal 4 for connecting an electronic component 3 on the ceramic substrate body 2, and a wiring unit 5 forming an electronic wiring pattern over the ceramic substrate body 2. The thickness of the terminal 4 is configured to be greater than the thickness of the wiring unit 5.

This application claims benefit to the provisional U.S. Application 61/750541, filed on Jan. 9, 2013.

### TECHNICAL FIELD

The present disclosure relates to a ceramic substrate and to an electronic component module using the ceramic substrate.

### Description of the Related Art

In recent years, the development of an electronic component module made up of an electronic component mounted on a ceramic substrate has progressed. A ceramic substrate is advantageous in having beneficial resistance to heat and humidity, and given the visible-light reflectivity of the material itself As such, an electronic component module is being developed in which a light-emitting diode (hereinafter, LED) is mounted as the electronic component on the ceramic substrate.

The electronic component module having the LED mounted on the ceramic substrate is, for example, used as high-power LED module or as an LED module for a liquid crystal backlight.

A representative example of a conventional ceramic substrate used in such an electronic component module includes a ceramic layer, a wiring unit formed by applying patterning to the surface of the ceramic layer and connecting to the electronic component, and a terminal formed on the surface of the ceramic layer and electrically connected to the wiring unit (see Patent Literature 1).

A ceramic substrate is sought such that, when the LED is mounted thereon, the ceramic substrate effectively reflects the light emitted by the LED. Therefore, an electrically-insulating reflective film having high reflectivity in the visible spectrum is formed using resin or similar on the surface of the ceramic substrate having the LED mounted thereon.

### CITATION LIST

### Patent Literature

### [Patent Literature 1]

Japanese Patent Application No. 2010-010469

### SUMMARY

As described above, a light-emitting module is manufactured by forming a reflective film on the surface of a ceramic substrate and subsequently electrically connecting an electronic component to a terminal on the substrate surface.

As such, when an electronic component such as an LED is mounted on the surface of the ceramic substrate after the reflective film has been formed, mounting becomes difficult in cases where the surface has poor planarity. Thus, good planarity is sought for the surface of the ceramic substrate after reflective film formation.

However, when the reflective film is formed over the ceramic substrate, no reflective film is formed over the terminal. Thus, the area where the reflective film is not formed has a low surface height relative to the area where the reflective film is formed, which decreases the planarity of the ceramic substrate surface.

In consideration of the above-described problem, one non-limiting and exemplary Embodiment provides a ceramic substrate having good planarity despite a reflective film being formed on the surface of the substrate, and on which an electronic component such as an LED is mountable.

In one general aspect, a ceramic substrate comprises: a ceramic substrate body; at least one terminal arranged on the ceramic substrate body for connecting an electronic component; and at least one wiring unit arranged on the ceramic substrate body and forming an electronic wiring pattern, wherein the terminal is greater in thickness than the wiring unit.

With the above structure, the ceramic substrate of the disclosure is configured such that the terminal thickness is greater than the wiring unit thickness, and is thus suited for mounting the electronic component on the substrate surface having the reflective film formed thereon.

That is, when the reflective film is formed over the surface of the ceramic substrate having the terminal and the wiring unit as described above, the reflective film is typically not formed over the terminal but is formed over the surface of the wiring unit. Accordingly, the surface of a typical, conventional ceramic substrate is configured such that the wiring unit on which the reflective film is formed has a greater surface height than the terminal. Thus, the planarity of the ceramic substrate is diminished. This is not beneficial in terms of mounting the electronic component on the terminal.

In contrast, the ceramic substrate of the present disclosure is configured such that the thickness of the terminal is greater than the thickness of the wiring unit. This reduces the difference between the surface height of the terminal and the surface height of the reflective film formed over the wiring unit. Accordingly, greater planarity is achieved after the formation of the reflective film, in comparison to the aforementioned conventional ceramic substrate.

Thus, the ceramic substrate pertaining to the disclosure is suitable for mounting the electronic component after the formation of the reflective film on the surface of the ceramic substrate. For example, this simplifies the mounting of an electronic component such an LED extending over the terminal and the reflective film surface over the wiring unit.

Accordingly, the ceramic substrate of the disclosure is suitable for mounting an electronic component such as an LED after the formation of the reflective film.

These general and specific aspects may be implemented using a manufacturing method.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

FIG. 1 is a cross-sectional diagram of an electronic component module using a ceramic substrate pertaining to Embodiment 1, where portion (a) depicts the top of the electronic component module and portion (b) depicts a cross-section taken along line A-A of portion (a).

FIG. 2 is a flowchart of a manufacturing method for the ceramic substrate pertaining to Embodiment 1.

FIG. 3 is a cross-sectional diagram of the ceramic substrate after a ceramic substrate body preparation step, pertaining to the ceramic substrate manufacturing method of Embodiment 1.

FIG. 4 is a cross-sectional diagram of the ceramic substrate after the first metal unit formation step, in the manufacturing method of the ceramic substrate pertaining to Embodiment 1.

FIG. 5 is a cross-sectional diagram of the ceramic substrate after the second metal unit formation step, in the manufacturing method of the ceramic substrate pertaining to Embodiment 1.

FIG. 6 is a cross-sectional diagram of the ceramic substrate after a reflective film formation step.

### DETAILED DESCRIPTION

The following describes the details of an electronic component module of the present invention, with reference to the accompanying drawings.

### Embodiment 1

### Configuration of Electronic Component Module 6 Using Ceramic Substrate 1

First, the overall configuration of an electronic component module using the ceramic substrate pertaining to Embodiment 1 is described.

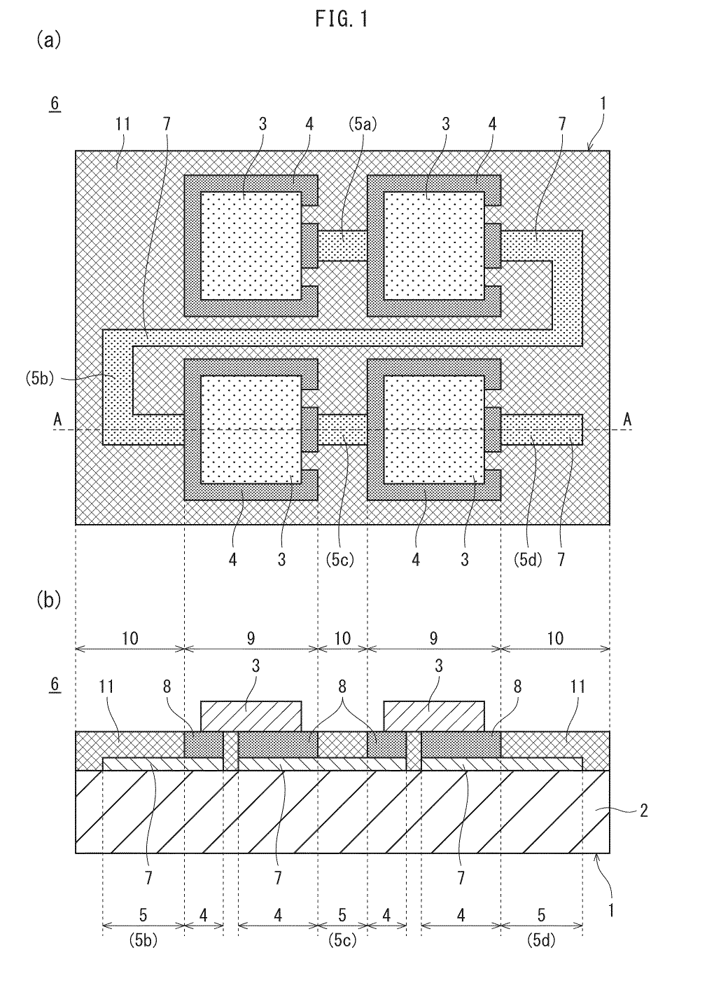

FIG. 1 is a cross-sectional diagram of the electronic component module using the ceramic substrate pertaining to Embodiment 1. Section (a) of FIG. 1 depicts a top-down view of the electronic component module. Section (b) of FIG. 1 depicts a cross-sectional view taken along line A-A of section A.

As shown in FIG. 1, a ceramic substrate 1 includes a ceramic substrate body 2, at least one terminal 4 formed to connect an electronic component 3 to the ceramic substrate body 2, and at least one wiring unit 5 forming a desired electronic wiring pattern over the ceramic substrate body 2.

The electronic component module 6 also includes the ceramic substrate 1 and an electronic component 3 mounted on the terminal 4 thereof.

The electronic component 3 is electrically connected to the ceramic substrate 1. In Embodiment 1, an LED serves as the electronic component 3.

The ceramic substrate 1 shown in FIG. 1 has four of the electronic component 3 mounted thereon. Also, the wiring unit 5 (i.e., 5a through 5d) is provided in plurality and the four electronic components 3 are connected in series to form the wiring pattern. Here, wiring units 5a through 5c each connect two of the electronic components 3 while wiring unit 5d connects the outermost electronic component 3 to the outside.

The wiring unit 5 is made up of a first metal unit 7 formed over the ceramic substrate 1.

The terminal 4 is made up of a first metal unit 7 formed over the ceramic substrate 1, and a second metal unit 8 formed over a top surface of the first metal unit 7.

That is, the first metal unit 7 is formed across the terminal 4 and the wiring unit 5, and the second metal unit 8 is layered over a portion of the surface of the first metal unit 7 (said portion corresponding to the terminal 4). Thus, each portion where the first metal unit 7 and the second metal unit 8 overlap forms the terminal 4, and each portion where the second metal unit 8 is not layered over the first metal unit 7 forms the wiring unit 5.

Accordingly, as shown in section (b) of FIG. 1, the thickness of the terminal 4 is equal to the total thickness of the first metal unit 7 and the second metal unit 8, and is accordingly greater than the thickness wiring unit 5, made up of the first metal unit 7 alone.

Further, as shown in FIG. 1, the surface of the ceramic substrate 1 has a mounting area 9 on which the electronic component 3 is mounted, and a non-mounting area 10 formed in all other areas. The terminal 4 is on the mounting area 9. Also, the non-mounting area 10 has the wiring pattern formed thereon as the wiring unit 5, and has the reflective film 11 formed thereover.

The reflective film 11 is formed of a resin or the like containing aluminium oxide (Al₂O₃).

The thickness of the reflective film 11 may be adjusted as appropriate for the mounting method and so on. The thicker the reflective film 11, the better the reflective index.

(Component Configuration in Ceramic Substrate 1)

The following specifically describes the individual components of the ceramic substrate 1.

The ceramic substrate body 2 is generally formed of aluminium oxide (Al₂O₃), in a high temperature co-fired ceramic (hereinafter, HTCC).

The first metal unit 7 is formed from a first metal layer (of titanium), a second metal layer (of copper), and a third metal layer (also of copper), layered in the stated order.

Specifically, the first metal unit 7 is formed as follows: a 50 nm thin film of titanium (Ti) is formed using radio frequency sputtering (hereinafter, RF sputtering), which is a form of dry plating, to serve as the first metal layer, then a 100 nm thin film of copper (Cu) is formed over the thin film of titanium using RF sputtering to serve as the second metal layer, and a 5 μm to 30 μm thin film of copper (Cu) is formed thereover using electroplating, which is a form of wet plating, to serve as the third metal layer.

That is, the first metal unit 7 is formed of three stacked layers of metallic thin-film, namely a titanium (Ti) layer formed by RF sputtering, a copper (Cu) layer formed by RF sputtering, and a copper (Cu) layer formed by electroplating. Here, the layer of titanium (Ti) formed using RF sputtering and the layer of copper (Cu) formed without using electroplating (i.e., using RF sputtering) are proportionally much thinner than the layer of copper (Cu) formed using electroplating. Accordingly, in practice, the first metal unit 7 is effectively made of the layer of copper (Cu) formed using electroplating.

Also, within the first metal unit 7, the thickness of the layer of copper (Cu) formed last using electroplating may be adjusted as appropriate, in consideration of usage and the like.

Next, the second metal unit 8 is a 20 μm to 50 μm thin film of copper (Cu) formed using the electroplating method, which is a wet plating method. The thickness (i.e., film thickness) of the second metal unit 8 may be adjusted as appropriate, in consideration of usage and the like.

According to Embodiment 1, the terminal 4 and the wiring unit 5 are, in practice, formed from a common metal layer. Specifically, the terminal 4 and the wiring unit 5 are formed from the layer of copper (Cu) that is formed using electroplating.

Accordingly, when the terminal 4 and the wiring unit 5 are formed using electroplating, making the terminal 4 and the wiring unit 5 from a common metal, specifically from copper (Cu), enables the previously-formed first metal unit 7 (i.e., the wiring unit 5) to serve as an electrode in the formation of the second metal unit 8. Accordingly, the second metal unit 8 is formed more simply and at lower cost.

The thickness of the wiring unit 5 corresponds to the thickness of the first metal unit 7, and as such, the wiring unit 5 is thin when the first metal unit 7 is configured to be thin. Accordingly, making the first metal unit 7 thin enables the wiring patterns to be made finer and more precise, and also provides a reduction in the risk of short-circuiting between wiring patterns.

This effect is specifically described below.

The amount of space required as insulation space for the wiring unit 5 is dependent on the thickness thereof. The thicker the wiring unit 5, the more space is needed for insulation space. Conversely, when the wiring unit 5 is thin, a narrower insulation space is sufficient.

For the ceramic substrate 1, the wiring unit 5 is made thinner by configuring the first metal unit 7 to be thinner. As such, the insulation space is correspondingly made smaller, making more area available. For example, when the thickness of the wiring unit 5 is on the order of 70 securing a sufficient insulation space of 50 μm is difficult. However, when the thickness of the wiring unit 5 is on the order of 10 μm, then securing 50 μm of insulation space is more than sufficient, thus relatively simplifying the configuration.

### [2] Manufacturing Method for Ceramic Substrate 1

The following describes a manufacturing method for the ceramic substrate 1 and a formation method of the reflective film pertaining to Embodiment 1.

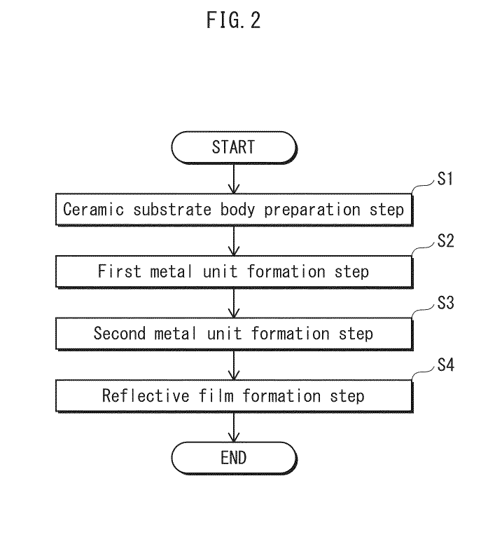

FIG. 2 is a flowchart of the manufacturing method for the ceramic substrate 1 and the formation method of the reflective film.

As shown, Embodiment 1 involves a multi-layered substrate manufacturing method that includes the following four steps:
S1: Ceramic Substrate Body Preparation Step
S2: First Metal Unit Formation Step
S3: Second Metal Unit Formation Step
S4: Reflective Film Formation Step

The following describes steps S1 and S2 in detail.

### [2]-(1) Ceramic Substrate Body Preparation Step S1

The ceramic substrate body preparation step S1 is a step of creating the ceramic substrate body 2.

In this step, a composition is formed by combining solid components of aluminium oxide (Al₂O₃) with an organic binder made of an organic solvent, such that the ratio of solid components to organic binder is 84:16 by mass, and the composition is made into a sheet, thus producing a green sheet.

The green sheet is layered in plurality to achieve a desired thickness, and then baked under pressure to produce the ceramic substrate body 2.

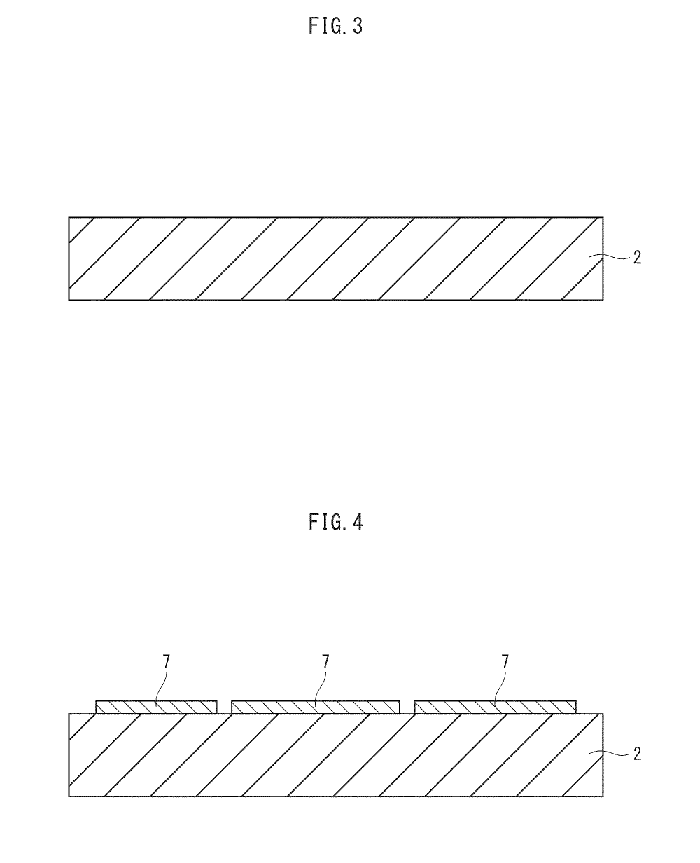

FIG. 3 is a cross-sectional diagram of the ceramic substrate body 2 after the ceramic substrate body preparation step, pertaining to the ceramic substrate 1 manufacturing method.

### [2]-(2) First Metal Unit Formation Step S2

The first metal unit formation step S2 involves forming the first metal unit 7 by layering three layers over the ceramic substrate body 2.

Specifically, the first metal unit 7 is formed as follows: a 50 nm thin film of titanium (Ti) is formed using RF sputtering, which is a form of dry plating, to serve as a first metal layer, then a 100 nm thin film of copper (Cu) is formed over the thin film of titanium using RF sputtering to serve as a second metal layer, and a 5 μm to 30 μm thin film of copper (Cu) is formed thereover using electroplating, which is a form of wet plating, to serve as a third metal layer.

Here, the first layer of titanium (Ti) and the second layer of copper (Cu) serve as seed layers.

The specifics of the formation of the first metal layer of titanium (Ti) followed by the formation of the second metal layer of copper (Cu) in the first metal unit 7 are described below.

Firstly, the first metal layer of titanium (Ti) in the first metal unit 7 is formed using RF sputtering as a dry plating method.

More specifically, a titanium (Ti) target is used as the sputtering target in an argon (Ar) gas atmosphere, with the ceramic substrate body 2 serving as the sputtering substrate, to form the titanium (Ti) layer to a thickness of 50 nm by applying high-frequency voltage between the sputtering target and the sputtering substrate.

The sputtering conditions are such that, prior to beginning the sputtering, the vacuum pressure (back pressure) in the sputtering device is 7×10⁻⁴ Pa or lower, and while the sputtering is being performed, the power is 250 W, the argon pressure is 3.3 Pa, and the temperature is set to 30° C.

Next, the second metal layer of copper (Cu) in the first metal unit 7 is formed using dry plating. This is performed similarly to the formation of the first metal layer of titanium (Ti) in the first metal unit 7, using RF sputtering as a dry plating method. More specifically, a copper (Cu) target is used as the sputtering target in an argon (Ar) gas atmosphere, and the copper (Cu) film is formed, with the ceramic substrate body 2 having the first layer of titanium (Ti) formed thereon serving as the sputtering substrate, to a thickness of 100 nm by applying high-frequency voltage between the sputtering target and the sputtering substrate.

The sputtering conditions are such that, after the formation of the titanium (Ti) film as the first metal layer of the first metal unit 7, the sputtering device remains in vacuum and continues on to form the copper (Cu) film as the second metal layer of the first metal unit 7. Here, the sputtering power is 200 W, the argon gas pressure is 2.4 Pa, and the temperature is set to 30° C.

According to the above, the first metal layer and the second metal layer of the first metal unit 7 are formed over the ceramic substrate body 2.

The following describes the method of forming the third metal layer of copper (Cu) in the first metal unit 7.

First, a resist is applied to a region of the ceramic substrate body 2 where the first metal unit 7 is not formed, and masking is performed. Afterward, electroplating is used to form a 10 μm copper (Cu) film over the second metal layer of the first metal unit 7.

Finally, the aforementioned resist is removed.

Here, the second metal layer and the third metal layer may be omitted in whole or in part.

FIG. 4 is a cross-sectional diagram of the ceramic substrate after the first metal unit formation step, in the manufacturing method of the ceramic substrate pertaining to Embodiment 1.

As shown, performing the first metal unit formation step S2 enables the formation of the first metal unit 7 over the ceramic substrate body 2.

### [2]-(3) Second Metal Unit Formation Step S3

Next, in the second metal unit formation step S3, the second metal unit 8 is formed over the first metal unit 7 on the ceramic substrate body 2.

First, a resist is applied to a region of the ceramic substrate body 2 where the second metal unit 8 is to be formed, and masking is performed over a region where the second metal unit 8 is not to be formed.

Next, the second metal unit 8 is formed in a region on the first metal unit 7 that is to serve as the terminal 4. Specifically, a copper (Cu) layer with a thickness of 30 μm is formed using electroplating as the wet plating method.

According to the above, the second metal unit 8 is layered over the first metal unit 7 on the ceramic substrate body 2, and the layered portion becomes the terminal 4.

Afterward, the aforementioned resist is removed and quick etching is performed.

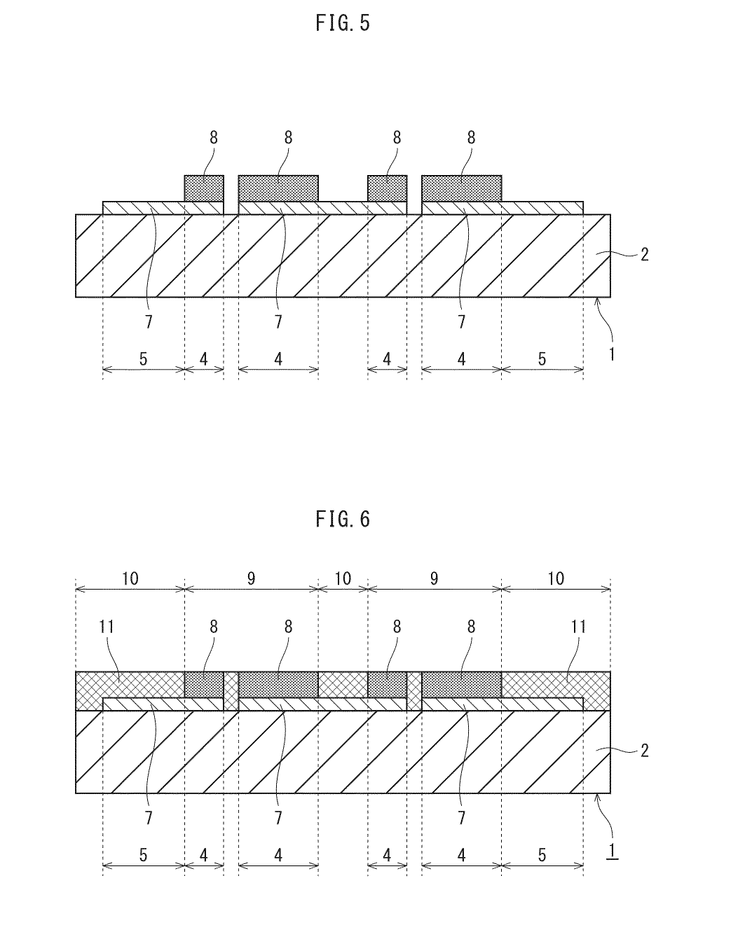

FIG. 5 is a cross-sectional diagram of the ceramic substrate during the second metal unit formation step in the manufacturing method of the ceramic substrate 1 pertaining to Embodiment 1.

As shown, performing the second metal unit formation step S3 provides the second metal unit 8 on the first metal unit 7 over the ceramic substrate body 2, and the formation of the second metal unit 8 provides the terminal 4.

### [2]-(4) Reflective Film Formation Step S4

Next, in the reflective film formation step S4, the reflective film 11 is formed in the non-mounting area 10 of the ceramic substrate body 2.

Specifically, a resin that contains aluminium oxide (Al₂O₃) or titanium oxide (TiO₂) is used in a screen printing method applied to the non-mounting area 10 of the ceramic substrate body 2. Afterward, the resin is dried to complete film formation.

Here, the height of the terminal 5 on the mounting area 9 is greater than the height of the wiring unit 5 on the non-mounting area 10. Thus, applying resin to the non-mounting area 10 without applying resin to the mounting area 9 (i.e., to regions other than the wiring unit 5) is easily accomplished. That is, the reflective film 11 is easily formed on the non-mounting area 10 only.

The resin that includes aluminium oxide (Al₂O₃) or titanium oxide (TiO₂) is, as described above, a silicone resin that includes aluminium oxide (Al₂O₃) or titanium oxide (TiO₂).

This concludes the explanation of the manufacturing method for the ceramic substrate 1 and the formation method for the reflective film on the surface of the ceramic substrate 1, pertaining to the present Embodiment.

### [3] Effects of Ceramic Substrate 1 in Embodiment 1

As described above, the ceramic substrate 1 comprises: a ceramic substrate body 2; at least one terminal 4 arranged on the ceramic substrate body 2 for connecting an electronic component 3; and at least one wiring unit 5 arranged on the ceramic substrate body 2 and forming an electronic wiring pattern, wherein the terminal 4 is greater in thickness than the wiring unit 5. As such, the ceramic substrate 1 is suitable for mounting the electronic component 3.

That is, a conventional ceramic substrate typically has the terminal and the wiring unit configured to have equal heights, such that when the reflective film is formed on the wiring unit, the thickness thereof makes a greater total height than the height of the terminal, which is not beneficial for mounting the electronic component.

In contrast, the ceramic substrate 1 of the present Embodiment has the terminal 4 configured to be thicker than the wiring unit 5.

Accordingly, forming the reflective film 11 on the surface of the ceramic substrate 1 over the wiring unit 5 without forming the reflective film 11 over the terminal 4 reduces the difference between the surface height of the terminal 4 and the surface height of the reflective film 11 formed over the wiring unit 5. As shown in the example of FIG. 1, the surface height of the terminal 4 and the surface height of the reflective film 11 formed over the wiring unit 5 are equal.

Accordingly, in contrast to a conventional ceramic substrate, the ceramic substrate 1 has greater surface planarity after the reflective film formation, and is thus suitable for mounting the electronic component 3.

For example, when the electronic component 3 is larger in size than the terminal 4, mounting the electronic component 3 on the terminal 4 may lead to the electronic component 3 being partly mounted over the reflective film 11. However, in such cases, the ceramic substrate 1 enables easy mounting in that the surface area where the electronic component 3 is mounted maintains high planarity.

Also, the ceramic substrate 1 produces the following effects.

The height of the terminal 4 formed on the mounting area 9 is greater than the height of the wiring unit 5 in the non-mounting area 10. Thus, the reflective film 11 is easily formed on the non-mounting area 10 only.

The first metal unit 7 is formed continuously across one or more terminal 4 and one or more wiring unit 5. That is, the terminal 4 and the wiring unit 5 are connected by the first metal unit 7.

Accordingly, heat produced by the electronic component 3 connected to the terminal 4 is effectively transferred from the terminal 4 to the wiring unit 5 and can then be dissipated from the surface of the wiring unit 5.

As such, the thermal stress imposed on the electronic component 3 can be reduced.

As a result, using the ceramic substrate enables the creation of an electronic component module with greater reliability.

Furthermore, the ceramic substrate 1 has the terminal 4 and the wiring unit 5 differ in thickness, such that a gradation is created therebetween that provides a separation of connection between the terminal 4 and the wiring unit 5. Therefore, the second metal unit 8 of the terminal 4 is usable as a mounting terminal. This plausibly makes solder resist unnecessary to the mounting process.

Further, reducing the conducting surface area of the terminal 4 produces a smaller area on which to apply gold plating and so on, thus providing reduced costs.

### (Thermal Expansion of Reflective Film 11 and Thickness Considerations)

Typically, resin material has a greater thermal expansion rate than copper. As such, when a reflective film of resin material is present under the electronic component, the reflective film is likely to expand under high temperatures and raise up the electronic component, potentially causing ineffective connection for the electronic component.

In contrast, the ceramic substrate 1 reduces the difference between the surface height of the terminal 4 and the surface height of the reflective film 11 formed over the wiring unit 5. Thus, thermal expansion of the reflective film 11 has less ability to lift up the electronic component 3.

Also, when the thickness of the reflective film 11 is less than the thickness of the second metal unit 8, then the surface of the reflective film 11 over the wiring unit 5 is lower than the terminal 4. As such, the reflective film 11 is beneficially prevented from lifting up the electronic component 3.

Conversely, when no thermal expansion occurs in the reflective film 11 during the mounting step, there is no risk that the electronic component 3 will be lifted up by the reflective film 11 formed therebeneath. In such a situation, the surface height of the reflective film 11 is beneficially greater than the surface height of the terminal 4.

Table 1, below, summarises an overview of reflective film 11 thickness settings.

(Variations on Embodiment 1)

| | Mounting Method | | | | | |
|---|---|---|---|---|---|---|
| | | | | Flip Chip Mounting | | |
| | | | | (Comparison of (terminal 4 + bonding | | |
| | Bonding Wire Mounting | | | height) to reflective film 11 height) | | |
| | Terminal 4 | Terminal 4 | Terminal 4 | Terminal 4 | Terminal 4 | Terminal 4 |
| | height > | height = | height < | height > | height = | height < |
| | Reflective | Reflective | Reflective | Reflective | Reflective | Reflective |
| | film 11 | film 11 | film 11 | film 11 | film 11 | film 11 |
| | height | height | height | height | height | height |
| Reflectivity | Low | Medium | High | Low | Medium | High |
| Mountability | Good | Good | Good | Bump | Bump | Bump |
| | | | | bonding: | bonding: Good | bonding: Good |
| | | | | Good | Surface | Surface |
| | | | | Surface | bonding: | bonding: |
| | | | | bonding: | Caution | Caution |
| | | | | Good | needed | needed |

*Ensure that no resist is located under the mounting chip when using bonding wire.

(Variations on Embodiment 1)
1. In the example shown in FIG. 1, the first metal unit 7 and the second metal unit 8 are layered to form the terminal 4. However, the terminal 4 may also be formed from portions where the first metal unit 7 is disposed alone, rather than only being formed of portions where the first metal unit 7 and the second metal unit 8 are layered.

Here, the terminal 4 includes layered portions of greater height (i.e., conductor film thickness) and portions of lower height. Each portion of the terminal 4 is usable for changing the mounted height of the electronic component by having the electronic component mounted thereon.

As such, when mounting another electronic component in the vicinity of the LED serving as the electronic component 3, for example, mounting the LED over the second metal unit 8 while mounting the other electronic component over the first metal unit 7 enables a reduction in the amount of obstruction that the other electronic component produces for the light of the LED.

The effects of this approach are also achievable in cases where the reflective film 11 is not formed.
2. Although the ceramic substrate body 2 is described as being formed of aluminium oxide (Al₂O₃) in an HTCC, other materials may also be used, such as aluminium nitride (AlN) likewise in an HTCC, or a combination of aluminium oxide (Al₂O₃) and glass (SiO₂) in low-temperature co-fired ceramics (hereinafter, LTCC).
3. Also, although the material for the first metal layer of the first metal unit 7 is described as being titanium (Ti), one or more of another metal such as nickel (Ni), platinum (Pt), gold (Au), a nickel-chromium alloy (NiCr), aluminium (Al), copper (Cu), or tungsten (W) may also be used.
4. Further, although the first metal unit 7 (or rather, the third metal layer in the first metal unit 7) and the second metal unit 8 are described as being made of copper (Cu), another material that is low in electrical resistivity, such as gold (Au) or silver (Ag), may also be applied using electroplating or printing.

Further, although the above Embodiment describes the first metal layer and the second metal layer of the first metal unit 7 as being formed using RF sputtering, no such limitation is intended. For example, other methods such as vacuum deposition, ion beam deposition, other dry plating methods, and other wet plating methods such as non-electroplating methods may also be used.
5. The ceramic substrate 1 shown in FIG. 1 has the electronic component 3 mounted thereon in plurality, and also has the wiring unit 5 provided in plurality. However, quantity of electronic components mounted on the ceramic substrate 1 may be any number greater than or equal to one. Also, the quantity of wiring units 5 provided on the ceramic substrate 1 is not limited to being plural, but may be a single unit.

### Embodiment 2

The ceramic substrate of Embodiment 2 is configured similarly to that of Embodiment 1 illustrated in FIG. 1. The first metal unit 7 formed on the ceramic substrate body 2 is formed continuously so as to extend across at least one terminal 4 and at least one wiring unit 5. That is, the terminal 4 and the wiring unit 5 are connected by the first metal unit 7.

The ceramic substrate of Embodiment 2 also has a conductive wiring unit film covering the entire surface of the terminal 4 and the wiring unit 5.

The conductive wiring unit film, which is not diagrammed, is formed over the surface of the first metal unit 7 on the wiring unit 5 and over the surface of the second metal unit 8 on the terminal 4.

The reflective film 11 is then formed so as to cover the conductive wiring unit film. After the reflective film 11 has been formed, the ceramic substrate has the wiring film arranged between the second metal unit and the reflective film 11 for the terminal 4, and has the conductive wiring film arranged between the first metal unit 7 and the reflective film 11 for the wiring unit 5.

As such, the results described above for Embodiment 1 are also achieved with the ceramic substrate having the wiring unit film formed over the terminal 4 and the wiring unit 5.

Furthermore, heat produced by the electronic component 3 is effectively transferred from the terminal 4 to the wiring unit 5 via the wiring unit film and can then be dissipated from the surface of the wiring unit 5. Accordingly, the thermal stress imposed on the electronic component 3 is further reduced and the electronic component module using the ceramic substrate is made with greater reliability.

### INDUSTRIAL APPLICABILITY

The ceramic substrate and the electronic component module in which an electronic component is mounted onto the ceramic substrate are applicable to electronic component modules used in liquid crystal televisions and backlights for mobile phones with liquid crystal screens.

### REFERENCE SIGNS LIST

1 Ceramic substrate
2 Ceramic substrate body
3 Electronic component
4 Terminal
5 Wiring unit
6 Electronic component module
7 First metal unit
8 Second metal unit
9 Mounting area
10 Non-mounting area
11 Reflective film

1. A ceramic substrate, comprising:
a ceramic substrate body;
at least one terminal arranged on the ceramic substrate body for connecting an electronic component; and
at least one wiring unit arranged on the ceramic substrate body and forming an electronic wiring pattern, wherein
the terminal is greater in thickness than the wiring unit.

2. The ceramic substrate of claim 1, wherein
a surface of the ceramic substrate body is divided into:
a mounting area where the terminal is arranged and where the electronic component is to be mounted; and
a non-mounting area where the wiring unit is arranged, and
a reflective film is formed over the wiring unit in the non-mounting area.

3. The ceramic substrate of claim 1, wherein
the terminal and the wiring unit are made of a substantially similar metal material.

4. The ceramic substrate of claim 3, wherein
the terminal and the wiring unit are made of a metal material that includes copper.

5. The ceramic substrate of claim 1, wherein
the terminal and the wiring unit are formed from a first metal unit and a second metal unit that is layered over a portion of the first metal unit,
the terminal is the portion of the first metal unit where the second metal unit is layered over the first metal unit, and
the wiring unit is a remaining portion of the first metal unit where the second metal layer is not present.

6. The ceramic substrate of claim 5, wherein
the first metal unit is formed continuously over the ceramic substrate body so as to extend across the terminal and the wiring unit.

7. An electronic component module, comprising
an electronic component mounted on the terminal of the ceramic substrate pertaining to claim 1.

8. The electronic component module of claim 7, wherein
the electronic component is a light-emitting diode.
